(19) United States
(12) Patent Application Publication
(10) Pub. No.: US 2013/0201638 A1
(43) Pub. Date: Aug. 8, 2013

(54) Flexible Display Device

(71) Applicant: Kwang-Bok Kim, Yongin-City (KR)

(72) Inventor: Kwang-Bok Kim, Yongin-City (KR)

(73) Assignee: SAMSUNG DISPLAY CO., LTD., Yongin-City (KR)

(21) Appl. No.: 13/594,251

(22) Filed: Aug. 24, 2012

(30) Foreign Application Priority Data
Feb. 2, 2012 (KR) 10-2012-0010852

(51) Int. Cl. H05K 7/00

(52) U.S. Cl. 361/749

(57) ABSTRACT

A flexible display device includes a display main body having flexibility; a first supporter which evenly supports a first side of the display main body; and a second supporter which evenly supports a second side of the display main body joined to the first side. During carrying, the display main body of the flexible display device is flexibly deformed and kept, and during use, the flexible display device is evenly unfolded and viewed. Accordingly, the flexible display device provides improved convenience in carrying and use.

### CLAIM OF PRIORITY

This application makes reference to, incorporates the same herein, and claims all benefits accruing under 35 U.S.C. §119 from an application earlier filed in the Korean Intellectual Property Office on the 2 Feb. 2012 and there duly assigned Serial No. 10-2012-0010852.

### BACKGROUND OF THE INVENTION

1. Field of the Invention

The present invention relates to a flexible display device, and more particularly, to a flexible display device manufactured in consideration of convenience to carry and use.

2. Description of the Related Art

Typically, a flexible display device is a device that has flexibility due to formation of a display unit on a flexible substrate formed of, for example, polyimide, and during carrying, the shape thereof is changed to reduce its volume.

However, this advantage in carrying may also be a disadvantage in use. That is, during use, the device needs to be fixed in a planar state so that the screen can be viewed in a proper manner. However, due to the flexible and movable characteristics of the device, it is likely that the screen may bend, and thus it may be difficult to view a planar screen without distortion.

Accordingly, there is a need for a flexible display device having a new structure that is built in consideration of convenience during use as well as convenience during carrying.

### SUMMARY OF THE INVENTION

The present invention provides a flexible display device that is improved so that, during carrying, a main body included therein is flexibly deformed and kept in this state, while during use, the main body is stretched so as to be planar, thereby allowing an image to be viewed without distortion.

According to an aspect of the present invention, there is provided a flexible display device including: a display main body having flexibility; a first supporter that evenly supports a first side of the display main body; and a second supporter that evenly supports a second side of the display main body, which is connected to the first side.

The first supporter may be a fixed supporter that is fixedly joined to the first side, and the second supporter may be a movable supporter that is placed inside the first supporter and is stretchable and rotatable.

The second supporter may include a telescopic member that is stretchable in a plurality of steps and a rotary axis member that rotatably supports the telescopic member.

The telescopic member may have a supporting groove into which the second side of the display main body is inserted.

The telescopic member may include a base member that is rotatably joined to the rotary axis member and a sliding member that slides into the base member and is placed therein, and a surface of the base member, which is opposite to the supporting groove, is planar.

A length of the base member may be equal to or greater than a half of a length of the second side of the display main body.

The display main body may have a rectangular shape in which a longer side and a shorter side are vertically connected to each other, wherein the first side is the shorter side of the rectangular shape and the second side is the longer side of the rectangular shape.

Regarding the flexible display device, during carrying, a main body included therein is flexibly deformed and kept in this state, and during use, the main body is stretched to be planar. Therefore, when the flexible display device is used, convenience during use as well as convenience in carrying may be improved.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a view of a flexible display device according to an embodiment of the present invention; and

FIGS. 2 to 4 are views illustrating how the flexible display device of FIG. 1 is used.

### DETAILED DESCRIPTION OF THE INVENTION

Hereinafter, embodiments of the present invention are described in detail below with reference to attached drawings.

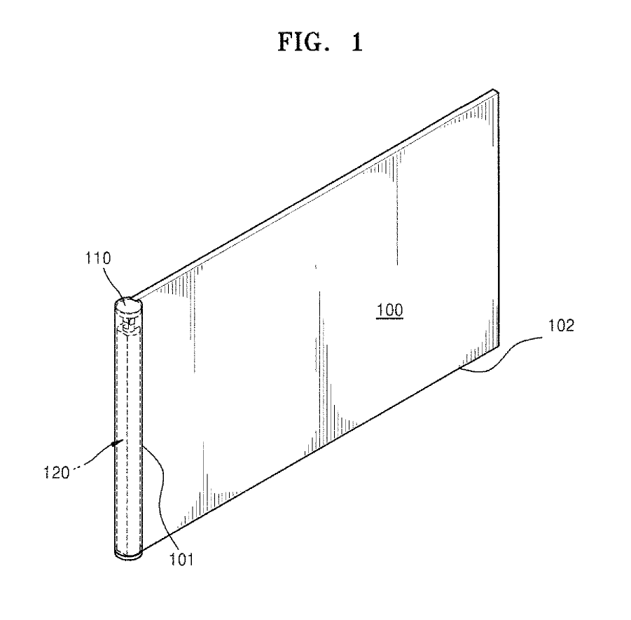

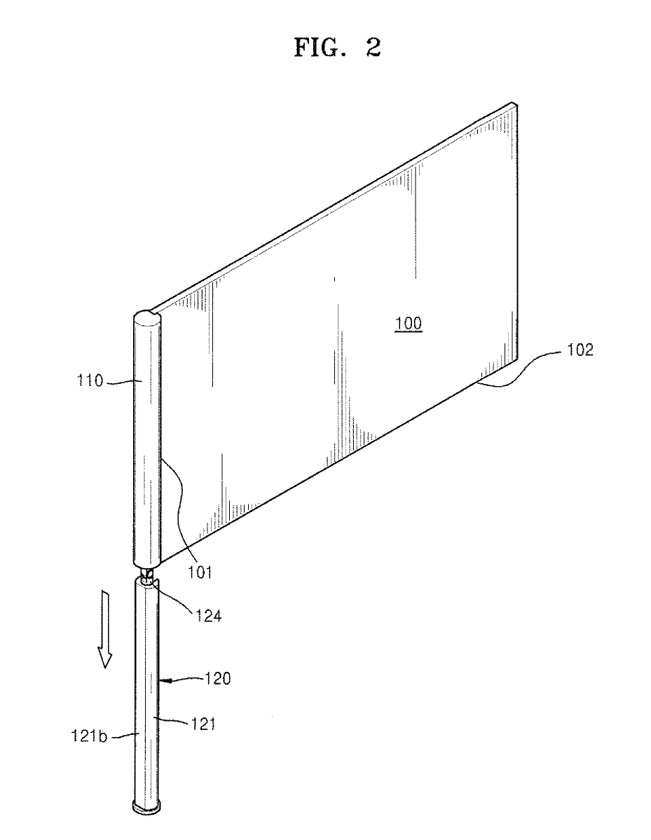

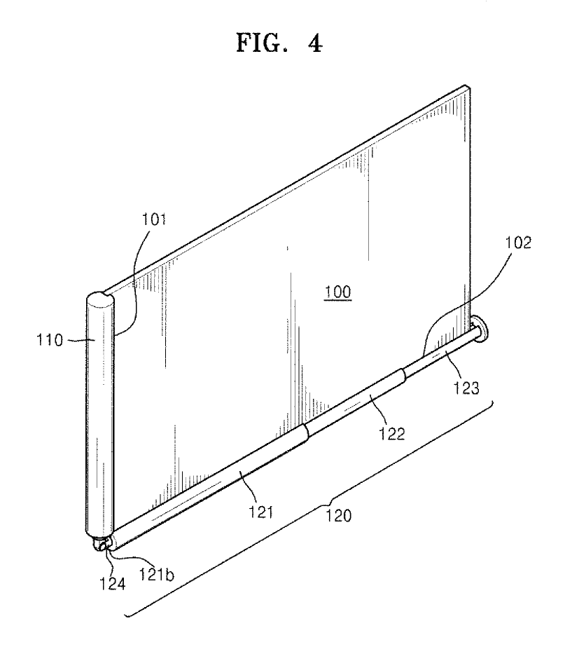

FIG. 1 is a view of a flexible display device according to an embodiment of the present invention, and FIGS. 2 to 4 are views illustrating how the flexible display device of FIG. 1 is used.

The flexible display device according to the present embodiment includes a display main body 100 having flexibility, and first and second supporters 110 and 120, respectively, that evenly support a first side 101 and a second side 102, respectively, connected to the first side 101 of the display main body 100.

The display main body 100 has a stack structure in which a thin film transistor and a light-emitting device for embodying an image, and an encapsulation layer for protecting the thin film transistor and the light-emitting device by covering them, are stacked on a flexible substrate. Because the display main body 100 includes a flexible substrate instead of a hard glass substrate, the display main body 100 is freely bent as long as its flexibility withstands.

Also, from among the first and second supporters 110 and 120, respectively, the first supporter 110 is a fixed supporter and is attached to the first side 101 of the display main body 100 so as to evenly support the first side 101. That is, the first side 101 of the display main body 100 is always supported evenly by the fixed first supporter 110. However, other sides may be freely bent.

The second supporter 120 evenly supports, from among the other sides which are freely bent, the second side 102 connected to the first side 101. The second supporter 120 is, unlike the fixed first supporter 110, a movable supporter that is stretchable and rotatable, and during non-use, as illustrated in FIG. 1, the second supporter 120 is in the first supporter 110, and during use, as illustrated in FIGS. 2 to 4, the second supporter 120 is pulled out of the first supporter 110 and is used.

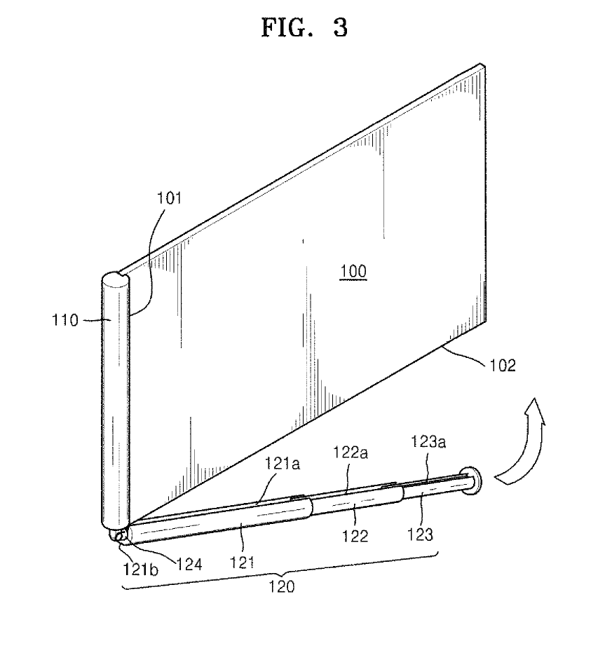

The second supporter 120 includes telescopic members 121, 122 and 123 that are stretchable in a plurality of steps like an antenna, and a rotary axis member 124 that rotatably supports the telescopic members 121, 122 and 123. Accordingly, as illustrated in FIG. 2, when the second supporter 120 is pulled out of the inside of the first supporter 110, the telescopic members 121, 122 and 123 and the rotary axis member 124 are pulled out together, and in this state, when the telescopic members 121, 122 and 123 are rotated about the rotary axis member 124, as illustrated in FIG. 3, the telescopic members 121, 122 and 123 approach the second side 102 of the display main body 100.

In this regard, the telescopic members 121, 122 and 123 have supporting grooves 121a, 122a and 123a, respectively, into which the second side 102 of the display main body 100 is inserted.

The telescopic members 121, 122 and 123 include a base member 121 that is rotatably jointed to the rotary axis member 124 and slide members 122 and 123 that slide into the base member 121, wherein the base member 122 has the greatest diameter among the telescopic members 121, 122 and 123 and a side of the base member 122, which is opposite to the supporting groove 121a, is a planar side 121b. The planar side 121b is usefully used when the display main body 100 stands. That is, the first supporter 110 supports a shorter side (the first side 101) of the display main body 100, which is rectangular, and the second supporter 120 supports a longer side (the second side 102) of the display main body 100. Typically, during use, the longer side is horizontal so that the screen can be viewed. In this regard, due to the planar side 121b of the base member 121, the display main body 100 may be erected by contacting the planar side 121b with a planar surface. To stably erect the display main body 100, a length of the base member 121 including the planar side 121b may be equal to or greater than a half of a length of the longer second side 102 of the display main body 100.

The flexible display device 100 may be used in the following manner.

First, during carrying, as illustrated in FIG. 1, the second supporter 120 which is a movable supporter is in the first supporter 110 which is a fixed supporter. In this case, sides of the display main body 100, other than the first side 101 to which the first supporter 110 is fixedly joined, are freely movable as long as flexibility of the display main body 100 withstands. Accordingly, the display main body 100 may be bent in half or rolled up against the first supporter 110 for carrying.

Also, when the flexible display device is used, as illustrated in FIG. 1, the display main body 100 is unfolded and only the first side 101 is evenly supported by the first supporter 110. In this case, however, because the display main body 100 is flexible, and thus the display main body 100 is arbitrarily bent during use to make viewing difficult, the second supporter 120 is stretched so as to evenly support the second side 102 of the display main body 100.

To do this, as illustrated in FIG. 2, the second supporter 120, which has been inserted into the first supporter 110, is pulled out of the first supporter 110. In this case, the telescopic members 121, 122 and 123 and the rotary axis member 124, which constitute the second supporter 120, are pulled out of the first supporter 110 by sliding.

In this state, as illustrated in FIG. 3, the slide members 122 and 123 of the telescopic members 121, 122 and 123 are pulled out of the base member 121, and are stretched to their maximum lengths, and the telescopic members 121, 122 and 123 are moved toward the second side 102 by rotating about the rotary axis member 124.

By doing so, the second side 102 of the display main body 100 is inserted into the supporting grooves 121a, 122a and 123a of the telescopic members 121, 122 and 123, respectively, so as to allow the even state of the display main body 100 to be maintained. Accordingly, because the first side 101 of the display main body 100, which is relatively short, is evenly supported by the first supporter 110, and because the second side 102, which is relatively long, is evenly supported by the second supporter 120, any interruption due to arbitrary bending of the display main body 100 during viewing may be prevented.

Also, if the planar side 121b of the base member 121 is placed on a planar surface, the display main body 100 may be erected. Accordingly, comfortable viewing is possible without use of hands.

Thus, in the case of a flexible display device having such a structure, during carrying, the main body is flexibly deformed and retrieved, and during use, the deformed main body is stretched for viewing. Thus, the flexible display device provides convenience in carrying and in use.

While the present invention has been particularly shown and described with reference to exemplary embodiments thereof, it will be understood by those of ordinary skill in the art that various changes in form and detail may be made therein without departing from the spirit and scope of the present invention as defined by the following claims.

What is claimed is:

1. A flexible display device, comprising:
a display main body having flexibility;
a first supporter which evenly supports a first side of the display main body; and
a second supporter which evenly supports a second side of the display main body, the second side being connected to the first side.

2. The flexible display device of claim 1, wherein the first supporter is a fixed supporter which is fixedly joined to the first side; and
wherein the second supporter is a movable supporter which is placed inside the first supporter and which is stretchable and rotatable.

3. The flexible display device of claim 2, wherein the second supporter comprises a telescopic member which is stretchable in a plurality of steps, and a rotary axis member which rotatably supports the telescopic member.

4. The flexible display device of claim 3, wherein the telescopic member has a supporting groove into which the second side of the display main body is inserted.

5. The flexible display device of claim 4, wherein the telescopic member comprises a base member which is rotatably joined to the rotary axis member and a sliding member which slides into the base member and is disposed therein; and
wherein a surface of the base member, which is opposite the supporting groove, is planar.

6. The flexible display device of claim 5, wherein a length of the base member is not less than one-half of a length of the second side of the display main body.

7. The flexible display device of claim 3, wherein the telescopic member comprises a base member which is rotatably joined to the rotary axis member and a sliding member which slides into the base member and is disposed therein; and
wherein a surface of the base member is planar.

8. The flexible display device of claim 7, wherein a length of the base member is not less than one-half of a length of the second side of the display main body.

9. The flexible display device of claim 1, wherein the display main body has a rectangular shape in which a longer side and a shorter side are vertically connected to each other;
wherein the first side of the display main body is the shorter side of the rectangular shape; and
wherein the second side of the display main body is the longer side of the rectangular shape.

10. The flexible display device of claim 9, wherein the first supporter is a fixed supporter which is fixedly joined to the first side; and
wherein the second supporter is a movable supporter which is placed inside the first supporter and which is stretchable and rotatable.

11. The flexible display device of claim 10, wherein the second supporter comprises a telescopic member which is stretchable in a plurality of steps, and a rotary axis member which rotatably supports the telescopic member.

12. The flexible display device of claim 11, wherein the telescopic member has a supporting groove into which the second side of the display main body is inserted.

13. The flexible display device of claim 12, wherein the telescopic member comprises a base member which is rotatably joined to the rotary axis member and a sliding member which slides into the base member and is disposed therein; and
wherein a surface of the base member, which is opposite the supporting groove, is planar.

14. The flexible display device of claim 13, wherein a length of the base member is not less than one-half of a length of the second side of the display main body.

15. The flexible display device of claim 11, wherein the telescopic member comprises a base member which is rotatably joined to the rotary axis member and a sliding member which slides into the base member and is disposed therein; and
wherein a surface of the base member is planar.

16. The flexible display device of claim 15, wherein a length of the base member is not less than one-half of a length of the second side of the display main body.

17. The flexible display device of claim 1, wherein the second supporter comprises a telescopic member which is stretchable in a plurality of steps, and a rotary axis member which rotatably supports the telescopic member.

18. The flexible display device of claim 17, wherein the telescopic member has a supporting groove into which the second side of the display main body is inserted.

19. The flexible display device of claim 18, wherein the telescopic member comprises a base member which is rotatably joined to the rotary axis member and a sliding member which slides into the base member and is disposed therein; and
wherein a surface of the base member, which is opposite the supporting groove, is planar.

20. The flexible display device of claim 19, wherein a length of the base member is not less than one-half of a length of the second side of the display main body.
